(19) United States
(12) Patent Application Publication
(10) Pub. No.: US 2025/0133844 A1
(43) Pub. Date: Apr. 24, 2025

(54) TRANSISTOR DEVICE AND PHOTOELECTRIC SENSING DEVICE

(71) Applicant: InnoCare Optoelectronics Corporation, Tainan City (TW)

(72) Inventors: Sheng-I Chen, Tainan City (TW); Hsin-Hung Lin, Tainan City (TW)

(73) Assignee: InnoCare Optoelectronics Corporation, Tainan City (TW)

(21) Appl. No.: 18/827,883

(22) Filed: Sep. 9, 2024

(30) Foreign Application Priority Data
Oct. 19, 2023 (TW) 112139896

(51) Int. Cl. H01L 27/146; H01L 29/417; H01L 29/49

(52) U.S. Cl. CPC H10F 39/8037; H10D 64/258; H10D 64/667; H10F 39/802

(57) ABSTRACT

A transistor device includes a substrate and a transistor. The transistor is disposed on the substrate and includes a gate, a gate dielectric layer, a semiconductor layer, a source and a drain. The gate dielectric layer is disposed on the gate. The semiconductor layer is disposed on the gate dielectric layer, and includes a first region and a second region. The first region at least partially overlaps with the gate in a normal direction of the substrate, the second region extends from the first region to an edge of the semiconductor layer, and the second region further includes a dopant compared to the first region. The source and the drain are disposed on the semiconductor layer, and are electrically connected to the second region of the semiconductor layer. At least one of the source and the drain does not overlap with the gate in the normal direction of the substrate.

### CROSS-REFERENCE TO RELATED APPLICATION

This application claims the priority benefit of Taiwan application serial no. 112139896, filed on Oct. 19, 2023. The entirety of the above-mentioned patent application is hereby incorporated by reference herein and made a part of this specification.

### BACKGROUND

### Technical Field

The disclosure relates to a semiconductor device, and in particular, to a transistor device and a photoelectric sensing device.

### Related Art

Compared to bottom-gate transistors, top-gate transistors have a relatively small gate-drain capacitance (Cgd) and are thus often used in photoelectric sensing devices. However, compared to bottom-gate transistors, top-gate transistors have a relatively poor radiation hardness.

Thus, in the field of photoelectric sensing devices, designing a transistor that has both a small gate-drain capacitance and a good radiation hardness is one of current issues in the art.

### SUMMARY

The disclosure provides a transistor device, in which a transistor can have a relatively small gate-drain capacitance and a relatively good radiation hardness.

The transistor device according to the disclosure includes a substrate and a transistor. The transistor is disposed on the substrate and includes a gate, a gate dielectric layer, a semiconductor layer, and a source and a drain. The gate dielectric layer is disposed on the gate. The semiconductor layer is disposed on the gate dielectric layer and includes a first region and a second region. The first region at least partially overlaps with the gate in a normal direction of the substrate, the second region extends from the first region to an edge of the semiconductor layer, and the second region further includes a dopant compared to the first region. The source and the drain are disposed on the semiconductor layer and are electrically connected to the second region of the semiconductor layer. At least one of the source and the drain does not overlap with the gate in the normal direction of the substrate.

The disclosure provides a photoelectric sensing device, in which a transistor can have a relatively small gate-drain capacitance and a relatively good radiation hardness.

The photoelectric sensing device according to the disclosure includes a substrate, a transistor, and a photosensitive element. The transistor is disposed on the substrate and includes a gate, a gate dielectric layer, a semiconductor layer, and a source and a drain. The gate dielectric layer is disposed on the gate. The semiconductor layer is disposed on the gate dielectric layer. A portion of the gate dielectric layer that is in contact with the semiconductor layer includes a silicon nitride-based material. The source and the drain are disposed on the semiconductor layer. The photosensitive element is disposed on the substrate and is coupled to the transistor. A threshold voltage shift of the transistor in a radiation hardness of the photoelectric sensing device is 0 V to 8 V.

Based on the above, in the transistor device (photoelectric sensing device) provided according to an embodiment of the disclosure, the drain does not overlap with the gate in the normal direction of the substrate, which can reduce the parasitic capacitance generated between the drain and the gate, or the portion of the gate dielectric layer that is in contact with the semiconductor layer includes a silicon nitride-based material, so the transistor in the transistor device (photoelectric sensing device) can have a relatively good radiation hardness.

### BRIEF DESCRIPTION OF DRAWINGS

FIG. 1A is a schematic partial top view of a photoelectric sensing device according to a first embodiment of the disclosure.

FIG. 1B is a schematic cross-sectional view according to an embodiment taken along line A1-A1′ in FIG. 1A.

FIG. 2A is a schematic partial top view of a photoelectric sensing device according to a second embodiment of the disclosure.

FIG. 2B is a schematic cross-sectional view according to an embodiment taken along line A2-A2′ in FIG. 2A.

FIG. 3A is a schematic partial top view of a photoelectric sensing device according to a third embodiment of the disclosure.

FIG. 3B is a schematic cross-sectional view according to an embodiment taken along line A3-A3′ in FIG. 3A.

FIG. 4A is a schematic partial top view of a photoelectric sensing device according to a fourth embodiment of the disclosure.

FIG. 4B is a schematic cross-sectional view according to an embodiment taken along line A4-A4′ in FIG. 4A.

FIG. 5A is a schematic partial top view of a transistor according to an embodiment of the disclosure.

FIG. 5B is a schematic partial top view of a transistor according to another embodiment of the disclosure.

FIG. 6A is a schematic view of a flow of a method for manufacturing a photoelectric sensing device according to an embodiment of the disclosure.

FIG. 6B is a schematic view of a flow of a method for manufacturing a photoelectric sensing device according to another embodiment of the disclosure.

FIG. 7A is a schematic partial cross-sectional view showing application of photoresists of different heights to the method for manufacturing the photoelectric sensing device according to an embodiment.

FIG. 7B is a relationship curve diagram of a concentration distribution of a dopant in a semiconductor layer according to an embodiment in FIG. 7A.

FIG. 7C is a relationship curve diagram of a concentration distribution of a dopant in the semiconductor layer according to another embodiment in FIG. 7A.

FIG. 7D is a relationship curve diagram of a concentration distribution of a dopant in the semiconductor layer according to still another embodiment in FIG. 7A.

FIG. 8A is a schematic partial cross-sectional view showing application of photoresists of different widths to the method for manufacturing the photoelectric sensing device according to an embodiment.

FIG. 8B is a relationship curve diagram of a concentration distribution of a dopant in a semiconductor layer according to an embodiment in FIG. 8A.

FIG. 8C is a relationship curve diagram of a concentration distribution of a dopant in the semiconductor layer according to another embodiment in FIG. 8A.

FIG. 8D is a relationship curve diagram of a concentration distribution of a dopant in the semiconductor layer according to still another embodiment in FIG. 8A.

FIG. 9A is a drain current-gate voltage (Id-Vg) characteristic curve diagram of a transistor in the photoelectric sensing device according to Example 1 of the disclosure.

FIG. 9B is a drain current-gate voltage characteristic curve diagram of the transistor in the photoelectric sensing device according to Comparative example 1.

### DESCRIPTION OF EMBODIMENTS

The disclosure may be understood by referring to the following detailed description with reference to the accompanying drawings. It is noted that for comprehension of the reader and simplicity of the drawings, in the drawings of the disclosure, only a part of the electronic device is shown, and specific components in the drawings are not necessarily drawn to scale. Moreover, the quantity and the size of each component in the drawings are only schematic and are not intended to limit the scope of the disclosure.

Throughout the specification and the appended claims of the disclosure, certain terms are used to refer to specific components. Those skilled in the art should understand that electronic device manufacturers may probably use different names to refer to the same components. This specification is not intended to distinguish between components that have the same function but different names. In the following specification and claims, the terms “including”, “containing”, “having”, etc., are open-ended terms, so they should be interpreted to mean “including but not limited to . . . ”. Therefore, when the terms “including”, “containing”, and/or “having” are used in the description of the disclosure, they specify existence of corresponding features, regions, steps, operations, and/or components, but do not exclude existence of one or more corresponding features, regions, steps, operations, and/or components.

Directional terminology mentioned in the specification, such as “top”, “bottom”, “front”, “back”, “left”, “right”, etc., is used with reference to the orientation of the drawings being described. Therefore, the used directional terminology is only intended to illustrate, rather than limit, the disclosure. The drawings illustrate general characteristics of methods, structures, and/or materials used in specific embodiments. However, these drawings should not be construed as defining or limiting the scope or nature covered by these embodiments. For example, for clarity, a relative size, a thickness, and a location of each film layer, region, and/or structure may be reduced or enlarged.

When a corresponding component (e.g., a film layer or a region) is described as being “on another component”, the component may be directly located on the another component, or other components may be present therebetween. On the other hand, when a component is described as being “directly on another component”, no other component is present therebetween. Moreover, when a component is described as being “on another component”, the two components have an up-down relationship in a top view, so the component may be above or below the another component, and the up-down relationship depends on the orientation of the device.

The terms such as “about”, “equal”, “same”, “substantially”, or “approximately” are generally interpreted as being within a range of plus or minus 20% of a given value or range, or as being within a range of plus or minus 10%, plus or minus 5%, plus or minus 3%, plus or minus 2%, plus or minus 1%, or plus or minus 0.5% of the given value or range.

The ordinal numbers used in the specification and claims, such as “first”, “second”, etc., are used to modify components and do not imply and mean that the component/components are preceded by any ordinal numbers, and do not represent a sequence of one component with another, or a sequence in a manufacturing method. The use of these ordinal numbers is only intended to clearly distinguish between a component with a certain name and another component with the same name. It is possible that different terms are used in the claims and the specification, and accordingly, a first component in the specification may be a second component in the claims.

It is understood that the following embodiments may be replaced, rearranged, and mixed with features from several different embodiments to form other embodiments without departing from the spirit of the disclosure. As long as the features between the embodiments do not violate the spirit of the disclosure or conflict with each other, they may be mixed and matched in any manner.

Electrical connection or coupling as described in the disclosure may both refer to direct connection or indirect connection. In the case of direct connection, the terminal points of two components on the circuit are directly connected or are connected to each other via a conductor line segment. In the case of indirect connection, a switch, a diode, a capacitor, an inductor, another suitable component, or a combination of the above components is present between the terminal points of two components on the circuit, but the disclosure is not limited thereto.

In the disclosure, the thickness, length, and width may be measured by an optical microscope, and the thickness may be obtained by cross-sectional image measurement in an electron microscope, but the disclosure is not limited thereto. In addition, there may be a certain error between any two values or directions used for comparison. If a first value is equal to a second value, it is implied that there may be an error of about 10% between the first value and the second value; if a first direction is perpendicular to a second direction, the angle between the first direction and the second direction may be 80 degrees to 100 degrees; and if the first direction is parallel to the second direction, the angle between the first direction and the second direction may be 0 degrees to 10 degrees.

The electronic device of the disclosure may include a detection device, a display device, an antenna device (e.g., a liquid crystal antenna), a light-emitting touch device, a splicing device, a device with other suitable functions, or a combination of devices with the above functions, but is not limited thereto. The electronic device includes a rollable or flexible electronic device, but is not limited thereto. The electronic device may include, for example, liquid crystal, light-emitting diode (LED), quantum dot (QD), fluorescence, phosphor, other suitable materials, or a combination of the above. The light-emitting diode may include, for example, organic light-emitting diode (OLED), micro-LED, mini-LED, or quantum dot LED (QLED, QDLED), but is not limited thereto. The electronic device may include electronic components. The electronic components may include passive components and active components, such as a capacitor, a resistor, an inductor, a diode, a transistor, etc. The diode may include a light-emitting diode or a photodiode. The light-emitting diode may include, for example, an organic light-emitting diode (OLED), a mini LED, a micro LED, a quantum dot (QD) LED (e.g., QLED or QDLED), other suitable materials, or any combination of the above materials, but is not limited thereto. It is noted that the electronic device may be any combination of the above, but is not limited thereto. In addition, the shape of the electronic device may be rectangular, circular, polygonal, a shape with curved edges, or other suitable shapes. The electronic device may have a drive system, a control system, a light source system, a rack system, or other peripheral systems to support the display device or splicing device. It is noted that the electronic device may be any combination of the above, but is not limited thereto. The electronic device may include multiple components, and at least two components may be assembled to form a composite component. In the text below, a detection device will be taken as the electronic device to illustrate the content of the disclosure, but the disclosure is not limited thereto.

Exemplary embodiments of the disclosure will be illustrated below, and the same reference signs will be used in the figures and descriptions to represent the same or similar parts.

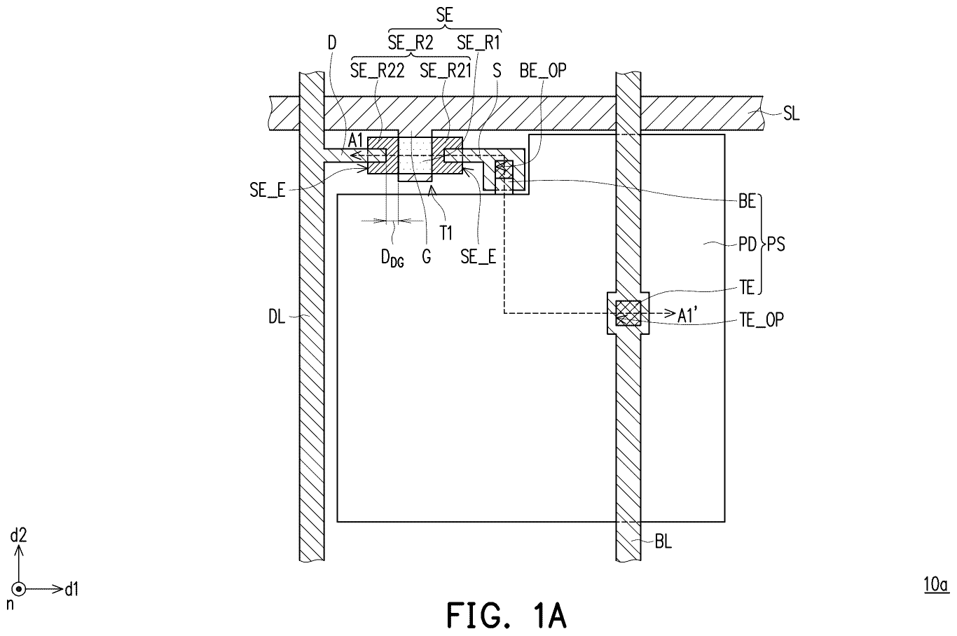

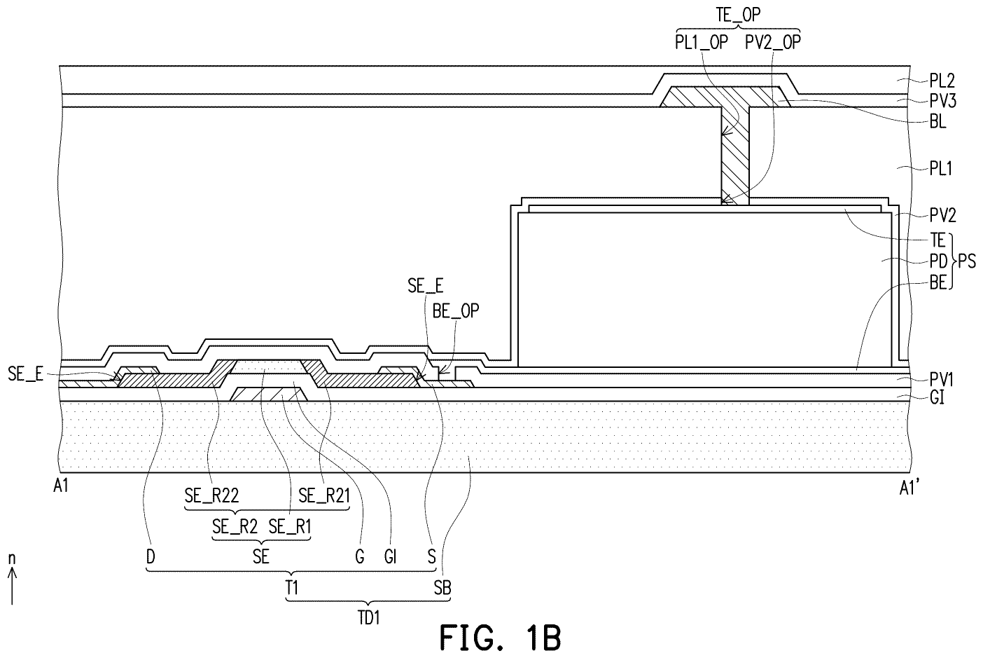

FIG. 1A is a schematic partial top view of a photoelectric sensing device according to a first embodiment of the disclosure, and FIG. 1B is a schematic cross-sectional view according to an embodiment taken along line A1-A1′ in FIG. 1A.

Referring to both FIG. 1A and FIG. 1B, a photoelectric sensing device 10a of this embodiment includes a transistor device TD1 and a photosensitive element PS. The photoelectric sensing device may be, for example, a direct X-ray sensing device or an indirect X-ray sensing device, but the disclosure is not limited thereto.

In this embodiment, the transistor device TD1 includes a substrate SB and a transistor T1, but the disclosure is not limited thereto.

The material of the substrate SB may include, for example, a hard material, a soft material, or a combination thereof. For example, the material of the substrate SB may include quartz, sapphire, polymethyl methacrylate (PMMA), polycarbonate (PC), polyimide (PI), polyethylene terephthalate (PET), other suitable materials, or a combination of the above materials, but the disclosure is not limited thereto.

The transistor T1 is, for example, disposed on the substrate SB. In this embodiment, the transistor T1 includes a gate G, a gate dielectric layer GI, a semiconductor layer SE, a source S, and a drain D.

The gate G is, for example, disposed on the substrate SB. In some embodiments, the material of the gate G may include molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), copper (Cu), silver (Ag), other suitable metals, or alloys or combinations of the above materials, but the disclosure is not limited thereto.

The gate dielectric layer GI is, for example, disposed on the gate G, and may, for example, cover the gate G. In some embodiments, the material of the gate dielectric layer GI may include an inorganic material (e.g., silicon oxide, silicon nitride, silicon oxynitride, or a stack layer of at least two of the above materials), an organic material (e.g., polyimide resin, epoxy resin, or acrylic resin), or a combination of the above, but the disclosure is not limited thereto. In this embodiment, the material of the gate dielectric layer GI includes a silicon nitride-based material, and the silicon nitride-based material may include SiN, SiON, SiCN, SiOCN, or a combination thereof. In some embodiments, the gate dielectric layer GI may include a single-layer structure or a multi-layer structure, but the disclosure is not limited thereto. However, when the gate dielectric layer GI includes a multi-layer structure, the portion (layer) of the gate dielectric layer GI that is in contact with the semiconductor layer SE includes a silicon nitride-based material. By configuring the material of the gate dielectric layer GI to include a silicon nitride-based material, and configuring the portion of the gate dielectric layer GI that is in contact with the semiconductor layer SE to include a silicon nitride-based material, the radiation hardness of the transistor T1 can be improved, which will be further described in experimental examples below.

The semiconductor layer SE is, for example, disposed on the gate dielectric layer GI, and, for example, at least partially overlaps with the gate G in a normal direction n of the substrate SB. In this embodiment, the material of the semiconductor layer SE includes a metal oxide, and the metal oxide may include indium gallium zinc oxide (IGZO), indium zinc oxide (IZO), indium gallium zinc tin oxide (IGZTO), or an organic semiconductor including a polycyclic aromatic compound, or a combination of the above, but the disclosure is not limited thereto. In other embodiments, the material of the semiconductor layer SE includes silicon, which may include low-temperature polysilicon (LTPS) or amorphous silicon (a-Si), but the disclosure is not limited thereto. For example, the material of the semiconductor layer SE may include but is not limited to amorphous silicon, polysilicon, germanium, compound semiconductor (e.g., gallium nitride, silicon carbide, gallium arsenide, gallium phosphide, indium phosphide, indium arsenide, and/or indium antimonide), alloy semiconductor (e.g., SiGe alloy, GaAsP alloy, AlInAs alloy, AlGaAs alloy, GalnAs alloy, GalnP alloy, and GaInAsP alloy), or a combination of the above.

In some embodiments, the semiconductor layer SE includes a first region SE_R1 and a second region SE_R2. The first region SE_R1 of the semiconductor layer SE, for example, at least partially overlaps with the gate G in the normal direction n of the substrate SB. In this embodiment, the first region SE_R1 of the semiconductor layer SE overlaps with the gate G in the normal direction n of the substrate SB to serve as a channel region of the transistor T1. The second region SE_R2 of the semiconductor layer SE, for example, extends from the first region SE_R1 to an edge SE_E of the semiconductor layer SE. Specifically, the semiconductor layer SE may include one first region SE_R1 and two second regions SE_R2. The two second regions SE_R2 may respectively be a second region SE_R21 and a second region SE_R22, and the second region SE_R21 and the second region SE_R22 respectively extend from two opposite ends of the first region SE_R1 to two edges SE_E of the semiconductor layer SE, but the disclosure is not limited thereto.

In this embodiment, the second region SE_R2 of the semiconductor layer SE additionally includes a dopant compared to the first region SE_R1. Specifically, the second region SE_R2 of the semiconductor layer SE may, for example, include an additional dopant compared to the first region SE_R1, and the dopant may include, for example, B, Ar, P, F, or a combination thereof. By configuring the second region SE_R2 of the semiconductor layer SE to additionally include the dopant compared to the first region SE_R1, the introduction of the dopant can increase oxygen vacancy in the second region SE_R2 of the semiconductor layer SE. The generation of oxygen vacancy means that valence electrons that are originally attracted by oxygen ions and originate from metal will be released to become free electrons. Based on the above, when oxygen vacancy increases, the free electrons in the second region SE_R2 of the semiconductor layer SE will also increase, which leads to a decrease in the impedance of the second region SE_R2 of the semiconductor layer SE such that the impedance value of the second region SE_R2 of the semiconductor layer SE can be lower than the impedance value of the first region SE_R1.

The source S and the drain D are, for example, disposed on the semiconductor layer SE and are, for example, separated from each other. In this embodiment, the source S and the drain D are in direct contact with the semiconductor layer SE and are electrically connected thereto, but the disclosure is not limited thereto. The materials included in the source S and the drain D may be the same as or similar to the material included in the gate G, which will not be repeatedly described herein.

In some embodiments, at least one of the source S and the drain D does not overlap with the gate G in the normal direction n of the substrate SB. In this embodiment, neither of the source S and the drain D overlaps with the gate G in the normal direction n of the substrate SB. In some embodiments, a distance DDG between the drain D and the gate G in a first direction d1 is greater than 0.5 micrometers, and the first direction d1 is perpendicular to the normal direction n of the substrate SB. By configuring the drain D not to overlap with the gate G, it is possible to reduce the parasitic capacitance generated between the drain D and the gate G, such that the transistor T1 can have a relatively small gate-drain capacitance (Cgd) and thus have relatively good electrical performance. Furthermore, it is also possible to reduce the load of a data line DL that is electrically connected to the drain D.

In addition, in this embodiment, the source S and the drain D are electrically connected to the second region SE_R2 of the semiconductor layer SE. Specifically, the source S and the drain D are, for example, respectively electrically connected to the second region SE_R21 and the second region SE_R22 located on two sides of the first region SE_R1. By electrically connecting the source S and the drain D respectively to the second region SE_R2 having relatively small impedance, it is possible to increase the ability of the gate G to control the first region SE_R1 (channel region) of the semiconductor layer SE with at least one of the source S and the drain D not overlapping with the gate G in the normal direction n of the substrate SB, such that the transistor T1 can have relatively good electrical performance.

Based on the above description of the components in the transistor T1, it is learned that the transistor T1 in this embodiment is a bottom-gate transistor and is an inverted-staggered bottom-gate transistor. As described above, the transistor T1 in this embodiment can have a relatively small gate-drain capacitance and relatively good radiation hardness, the reasons for which will not be repeatedly described herein.

The photosensitive element PS is, for example, disposed on the substrate SB and coupled to the transistor T1. In this embodiment, the photosensitive element PS does not overlap with the transistor T1 in the normal direction of the substrate SB, but the disclosure is not limited thereto. The photosensitive element PS may include, for example, a bottom electrode BE, a top electrode TE, and a semiconductor PD, and the semiconductor PD is, for example, disposed between the bottom electrode BE and the top electrode TE in the normal direction n of the substrate SB. The photosensitive element PS may be, for example, coupled to the source S of the transistor T1 via the bottom electrode BE, and may be, for example, coupled to a bias line BL (to be described later) via the top electrode TE. In some embodiments, the materials of the bottom electrode BE and the top electrode TE may include, for example, a transparent conductive material such as indium tin oxide (ITO), but the disclosure is not limited thereto. The material of the semiconductor PD may include, for example, amorphous silicon, but the disclosure is not limited thereto. In other embodiments, the semiconductor PD may include a monocrystalline material or a polycrystalline material. In some embodiments, the semiconductor PD includes a first layer (not shown), an intrinsic layer (not shown), and a second layer (not shown), and the first layer, the intrinsic layer, and the second layer are sequentially stacked in the normal direction n of the substrate SB, but the disclosure is not limited thereto.

In some embodiments, the semiconductor PD of the photosensitive element PS may receive light and generate carriers (e.g., electrons and/or holes). When the transistor T1 is not turned on, the carriers are stored in the photosensitive element PS. After the transistor T1 is turned on, the carriers stored in the photosensitive element PS may be, for example, transmitted to a processing circuit (not shown) via the bottom electrode BE and a data line DL (read line) (to be described later) coupled to the transistor T1 to serve the purpose of photoelectric sensing.

In this embodiment, when the photoelectric sensing device 10a performs photoelectric sensing, the threshold voltage shift of the transistor T1 in the radiation hardness of the photoelectric sensing device 10a is 0 V to 8 V, which will be further described in experimental examples below. In some embodiments, the threshold voltage shift of the transistor T1 in the radiation hardness of the photoelectric sensing device 10a may be 0 V to 6 V. In other embodiments, the threshold voltage shift of the transistor T1 in the radiation hardness of the photoelectric sensing device 10a may be 0 V to 4 V.

In some embodiments, the photoelectric sensing device 10a further includes an insulating layer PV1.

The insulating layer PV1 is, for example, disposed between the transistor T1 and the photosensitive element PS. In this embodiment, the insulating layer PV1 partially covers the source S of the transistor T1. Specifically, the insulating layer PV1 has an opening BE_OP that exposes a portion of the source S, and the bottom electrode BE of the photosensitive element PS is disposed on the insulating layer PV1 and may be electrically connected to the source S of the transistor T1 via the opening BE_OP, but the disclosure is not limited thereto. The material of the insulating layer PV1 may include, for example, an inorganic material (e.g., silicon oxide, silicon nitride, silicon oxynitride, or a stack layer of at least two of the above materials), an organic material (e.g., polyimide resin, epoxy resin, or acrylic resin), or a combination of the above, but the disclosure is not limited thereto.

In some embodiments, the photoelectric sensing device 10a further includes a scan line SL, a data line DL, and a bias line BL.

The scan line SL is, for example, disposed on the substrate SB and is coupled to the gate G of the transistor T1, and the scan line SL may serve to provide a scan signal to the corresponding transistor T1 to turn it on. In some embodiments, the scan line SL extends in the first direction d1, but the disclosure is not limited thereto. In this embodiment, the scan line SL and the gate G may be formed by the same conductor layer. Thus, the material of the scan line SL may be the same as the material of the gate G, which will not be repeatedly described herein.

The data line DL is, for example, disposed on the substrate SB and is coupled to the drain D of the transistor T1. The signal (carrier) generated by the photosensitive element PS may be transmitted to the data line DL via the drain D, and the data line DL may transmit the signal (carrier) to the processing circuit (not shown). In some embodiments, the data line DL extends in a second direction d2, and the second direction d2 may be perpendicular to the first direction d1, but the disclosure is not limited thereto.

In this embodiment, the data line DL belongs to the same layer as the source S and the drain D, but the disclosure is not limited thereto. In other embodiments, the data line DL may belong to the same layer as the bottom electrode BE of the photosensitive element PS. In still other embodiments, the data line DL may belong to the same layer as the bias line BL (to be described later). In still other embodiments, the data line DL belongs to a layer different from each of (1) the source S and the drain D, (2) the bottom electrode BE of the photosensitive element PS, and (3) the bias line BL.

In some embodiments, the data line DL may be farther from the gate G of the transistor T1 in the normal direction n of the substrate SB than from the drain D. By increasing the distance between the data line DL and the gate G, the parasitic capacitance of the data line DL can be reduced to reduce the load of the data line DL.

The bias line BL is, for example, disposed on the substrate SB and is coupled to the photosensitive element PS, and the bias line BL may serve to apply a voltage level to the photosensitive element PS. In some embodiments, the bias line BL extends in the second direction d2, but the disclosure is not limited thereto.

In some embodiments, the photoelectric sensing device 10a further includes an insulating layer PV2, a planarization layer PL1, an insulating layer PV3, and a planarization layer PL2.

The insulating layer PV2 is, for example, disposed between the bias line BL and the photosensitive element PS. In this embodiment, the insulating layer PV2 partially covers the top electrode TE of the photosensitive element PS. Specifically, the insulating layer PV2 has an opening PV2_OP that exposes a portion of the top electrode TE. The material of the insulating layer PV2 may include, for example, an inorganic material (e.g., silicon oxide, silicon nitride, silicon oxynitride, or a stack layer of at least two of the above materials), an organic material (e.g., polyimide resin, epoxy resin, or acrylic resin), or a combination of the above, but the disclosure is not limited thereto.

The planarization layer PL1 is, for example, disposed between the bias line BL and the insulating layer PV2. In this embodiment, the planarization layer PL1 also partially covers the top electrode TE of the photosensitive element PS. Specifically, the planarization layer PL1 also has an opening PL1_OP that exposes a portion of the top electrode TE. That is, the opening PL1_OP of the planarization layer PL1 may communicate with the opening PV2_OP of the insulating layer PV2 to form an opening TE_OP and together expose a portion of the top electrode TE, and the bias line BL is disposed on the planarization layer PL and may be electrically connected to the top electrode TE of the photosensitive element PS via the opening TE_OP, but the disclosure is not limited thereto. The material of the planarization layer PL1 may be, for example, an organic material such as polyimide resin, epoxy resin, acrylic resin, or a combination of the above, but the disclosure is not limited thereto.

The insulating layer PV3 is, for example, disposed on the bias line BL. In this embodiment, the insulating layer PV3 covers the bias line BL, but the disclosure is not limited thereto. Moreover, in this embodiment, the insulating layer PV3 may cover the photosensitive element PS and may serve to protect the photosensitive element PS. The material of the insulating layer PV3 may include, for example, an inorganic material (e.g., silicon oxide, silicon nitride, silicon oxynitride, or a stack layer of at least two of the above materials), an organic material (e.g., polyimide resin, epoxy resin, or acrylic resin), or a combination of the above, but the disclosure is not limited thereto.

The planarization layer PL2 is, for example, disposed on the insulating layer PV3. In this embodiment, the planarization layer PL2 covers the insulating layer PV3, but the disclosure is not limited thereto. The material of the planarization layer PL2 may include, for example, an organic material (e.g., polyimide resin, epoxy resin, or acrylic resin), but the disclosure is not limited thereto. In some embodiments, the planarization layer PL2 may have flatness, so that subsequent components may be stably formed on the planarization layer PL2. For example, a scintillator (not shown) may be disposed on the planarization layer PL2 subsequently, but the disclosure is not limited thereto.

Moreover, in some other embodiments, the photoelectric sensing device 10a may further include an insulating layer (not shown) disposed between the source S, the drain D and the semiconductor layer SE. This insulating layer has, for example, openings that expose portions of the second region SE_R21 and the second region SE_R22, and the source S and the drain D may be respectively electrically connected to the second region SE_R21 and the second region SE_R22 via these openings.

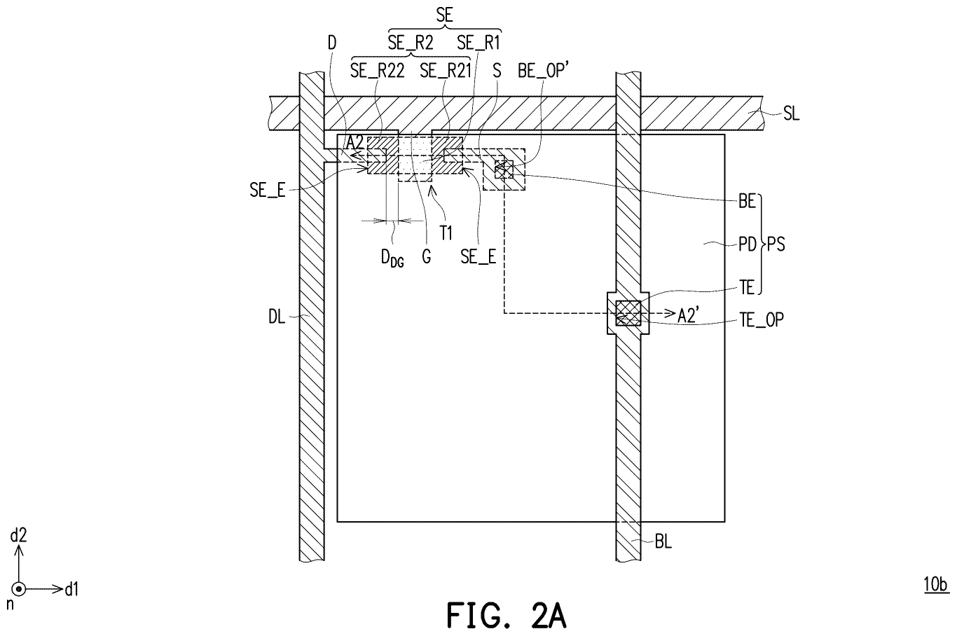

FIG. 2A is a schematic partial top view of a photoelectric sensing device according to a second embodiment of the disclosure, and FIG. 2B is a schematic cross-sectional view according to an embodiment taken along line A2-A2′ in FIG. 2A. It is noted that the reference signs and some contents of the embodiments in FIG. 1A and FIG. 1B may respectively apply to the embodiments in FIG. 2A and FIG. 2B, in which the same or similar reference signs represent the same or similar components, and descriptions of the same technical contents will be omitted.

Referring to both FIG. 2A and FIG. 2B, the main difference between a photoelectric sensing device 10b of this embodiment and the photoelectric sensing device 10a described above lies in that a photosensitive element PS′ at least partially overlaps with the transistor T1 in the normal direction n of the substrate SB.

Specifically, in this embodiment, the photoelectric sensing device 10b further includes a planarization layer PL3. The planarization layer PL3 is, for example, disposed between the photosensitive element PS′ and the transistor T1. In this embodiment, the planarization layer PL3 partially covers the source S of the transistor T1. Specifically, the planarization layer PL3 has an opening PL3_OP that exposes a portion of the source S. The opening PL3_OP of the planarization layer PL3 may communicate with an opening PV1_OP of the insulating layer PV1 to form an opening BE_OP′ and together expose a portion of the source S, and the bottom electrode BE of the photosensitive element PS′ is disposed on the planarization layer PL3 and may be electrically connected to the source S of the transistor T1 via the opening BE_OP′, but the disclosure is not limited thereto. The material of the planarization layer PL3 may be the same as or similar to the material of the planarization layer PL1, which will not be repeatedly described herein. In this embodiment, by configuring the photosensitive element PS′ to at least partially overlap with the transistor T1 in the normal direction n of the substrate SB, the surface area of the photosensitive element PS′ in the normal direction n of the substrate SB can be increased to have a relatively high fill factor (FF) and thus improve the photoelectric conversion efficiency of the photosensitive element PS′.

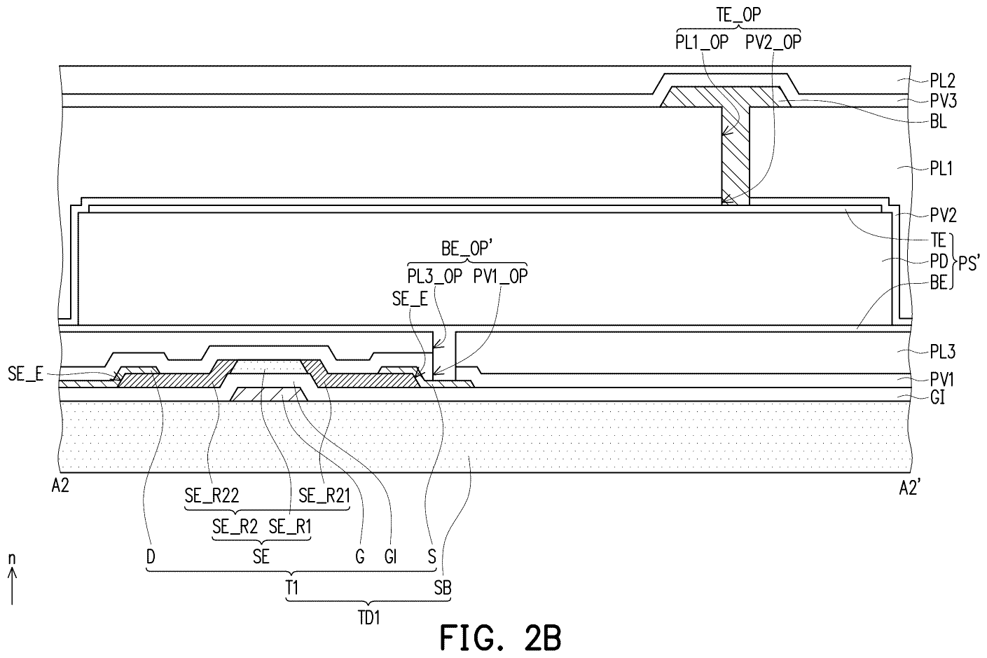

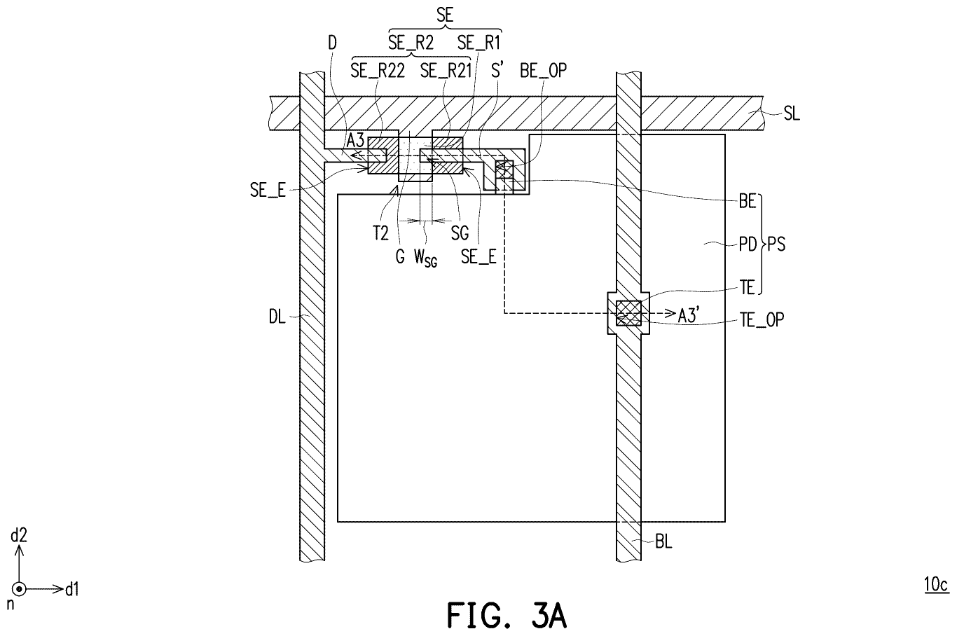

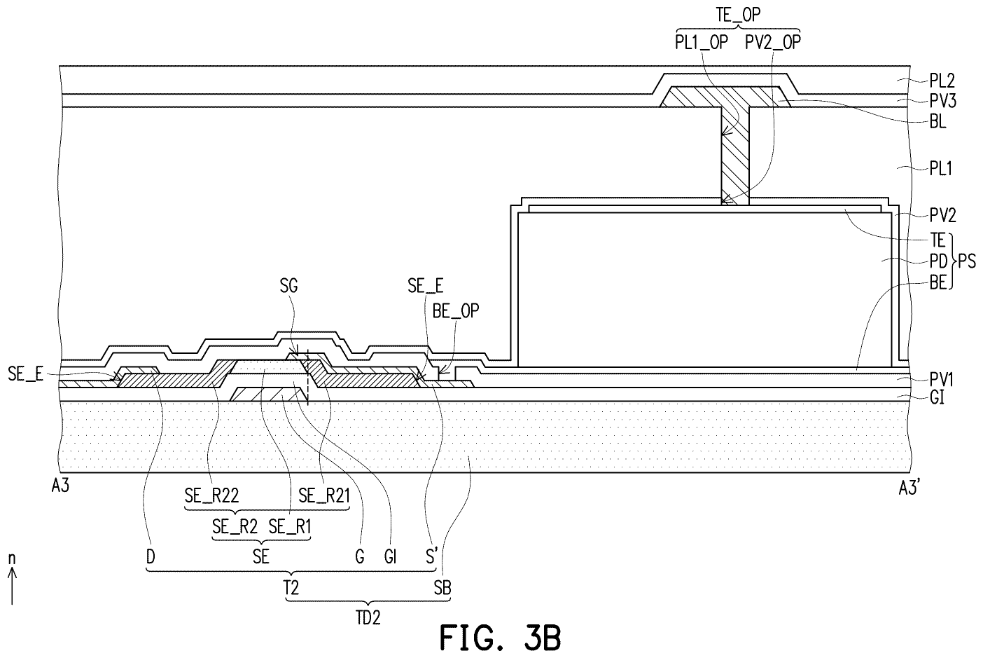

FIG. 3A is a schematic partial top view of a photoelectric sensing device according to a third embodiment of the disclosure, and FIG. 3B is a schematic cross-sectional view according to an embodiment taken along line A3-A3′ in FIG. 3A. It is noted that the reference signs and some contents of the embodiments in FIG. 1A and FIG. 1B may respectively apply to the embodiments in FIG. 3A and FIG. 3B, in which the same or similar reference signs represent the same or similar components, and descriptions of the same technical contents will be omitted.

Referring to both FIG. 3A and FIG. 3B, the main difference between a photoelectric sensing device 10c of this embodiment and the photoelectric sensing device 10a described above lies in that a source S′ in a transistor T2 of a transistor device TD2 at least partially overlaps with the gate G in the normal direction n of the substrate SB.

In this embodiment, the source S′ extends further along the first direction d1 compared to the source S in the embodiments described above, such that the source S′ can have a portion SG overlapping with the gate G in the normal direction n of the substrate SB. In some embodiments, a width WsG in the first direction d1 (a direction in which a portion of the source S′ extends further than the source S) of the portion SG of the source S′ overlapping with the gate G is less than 4 micrometers. By configuring the source S′ to at least partially overlap with the gate G in the normal direction n of the substrate SB, the distance between the source S′ and the drain D in the first direction d1 may be relatively reduced, so the path of the drain current in the transistor T2 can be relatively reduced to improve the electrical performance of the transistor T2.

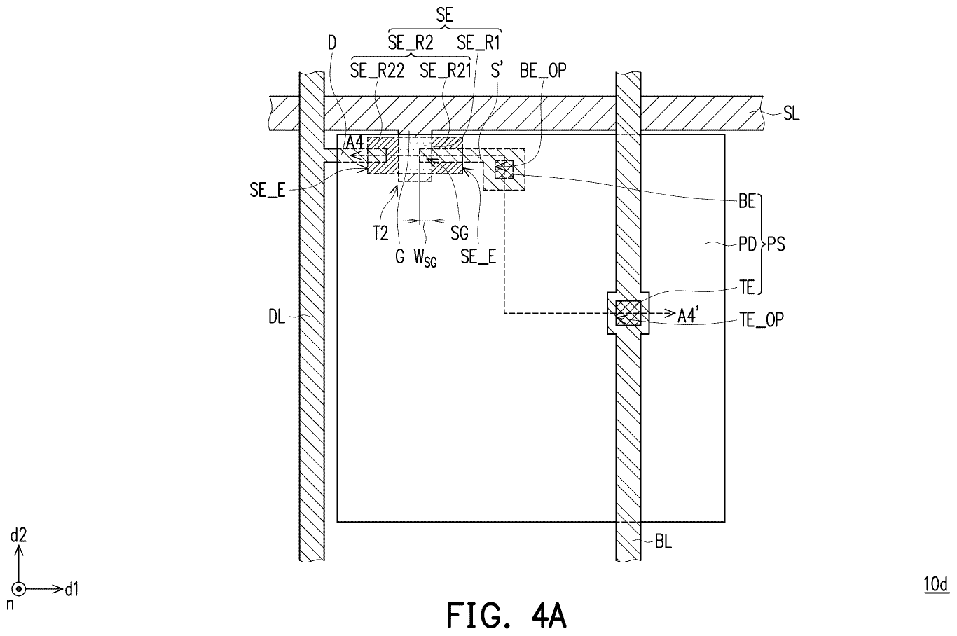

FIG. 4A is a schematic partial top view of a photoelectric sensing device according to a fourth embodiment of the disclosure, and FIG. 4B is a schematic cross-sectional view according to an embodiment taken along line A4-A4′ in FIG. 4A. It is noted that the reference signs and some contents of the embodiments in FIG. 2A, FIG. 2B, FIG. 3A, and FIG. 3B may respectively apply to the embodiments in FIG. 4A and FIG. 4B, in which the same or similar references signs represent the same or similar components, and descriptions of the same technical contents will be omitted.

Referring to both FIG. 4A and FIG. 4B, the main difference between a photoelectric sensing device 10d of this embodiment and the photoelectric sensing device 10c described above lies in that the photosensitive element PS′ at least partially overlaps with the transistor T1 in the normal direction n of the substrate SB.

Specifically, in this embodiment, the photoelectric sensing device 10d further includes a planarization layer PL3. Reference may be made to the technical contents about the photoelectric sensing device 10b above for descriptions of the planarization layer PL3, which will not be repeated herein. In this embodiment, by configuring the photosensitive element PS′ to at least partially overlap with the transistor T2 in the normal direction n of the substrate SB, the surface area of the photosensitive element PS′ in the normal direction n of the substrate SB can be increased to have a relatively high fill factor (FF) and thus improve the photoelectric conversion efficiency of the photosensitive element PS′.

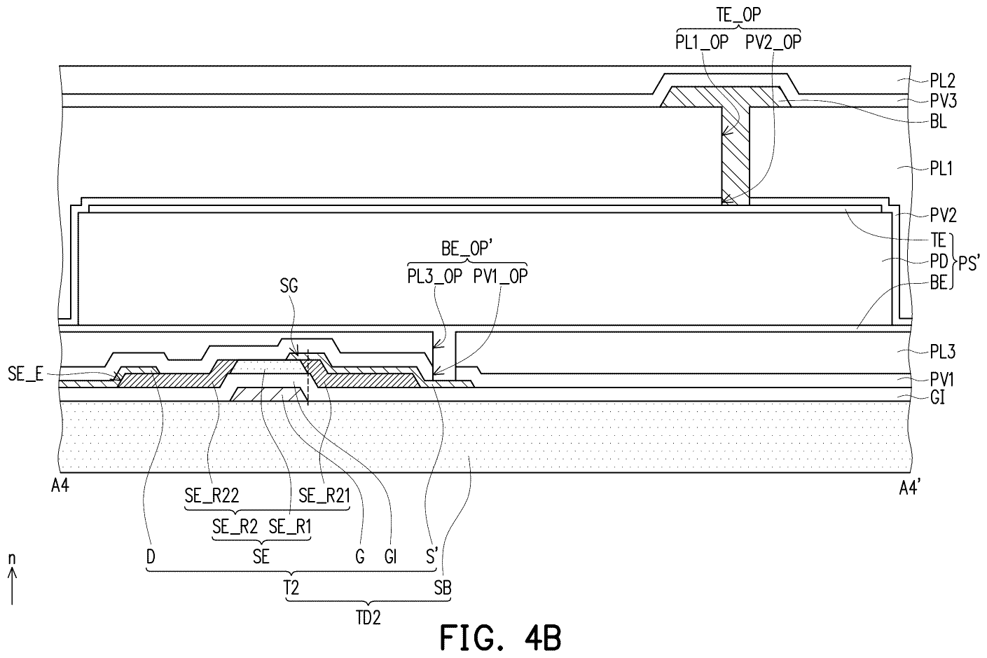

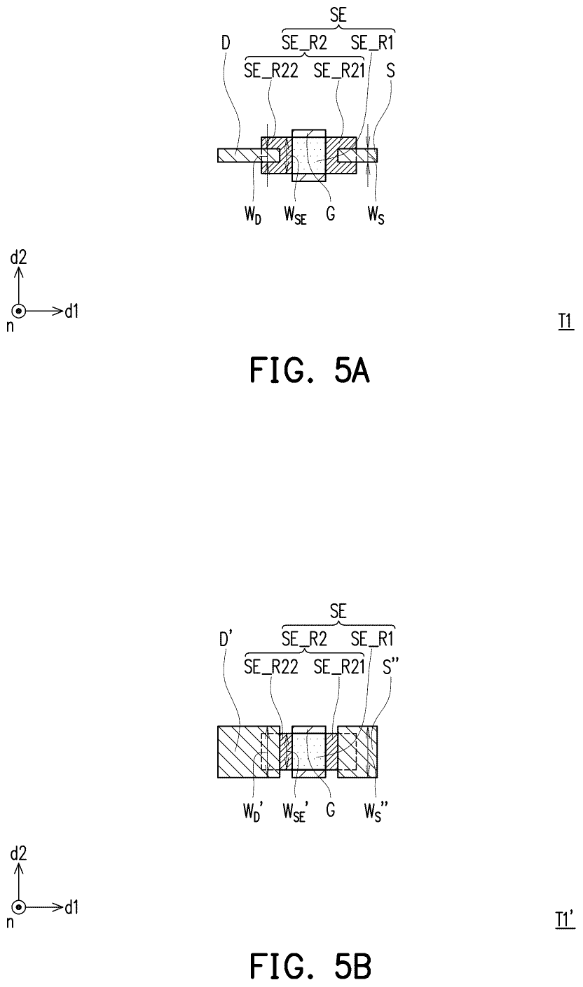

FIG. 5A is a schematic partial top view of a transistor according to an embodiment of the disclosure, and FIG. 5B is a schematic partial top view of a transistor according to another embodiment of the disclosure. It is noted that the reference signs and some contents of the embodiment in FIG. 1A may apply to the embodiments in FIG. 5A and FIG. 5B, in which the same or similar reference signs represent the same or similar components, and descriptions of the same technical contents will be omitted.

Referring to FIG. 5A, in this embodiment, a width W_{D} of the drain D in the transistor T1 in the second direction d2 may be less than a width W_{SE} of the semiconductor layer SE in the second direction d2. In addition, in this embodiment, a width W_{S} of the source S in the transistor T1 in the second direction d2 may also be less than the width W_{SE} of the semiconductor layer SE in the second direction d2, but the disclosure is not limited thereto.

Referring to FIG. 5B, in this embodiment, a width W_{D}′ of a drain D′ in a transistor T1′ in the second direction d2 may be greater than a width W_{SE}′ of the semiconductor layer SE in the second direction d2. In addition, in this embodiment, a width W_{S}″ of a source S″ in the transistor T1 in the second direction d2 may also be greater than the width W_{SE}′ of the semiconductor layer SE in the second direction d2, but the disclosure is not limited thereto.

It is noted that the size relationship between the drain D (or the drain D′), the source S (or the source S″), and the semiconductor layer SE shown in FIG. 5A and FIG. 5B may also apply to the photosensitive element 10b, the photosensitive element 10c, and the photosensitive element 10d described above, which will not be repeatedly described herein.

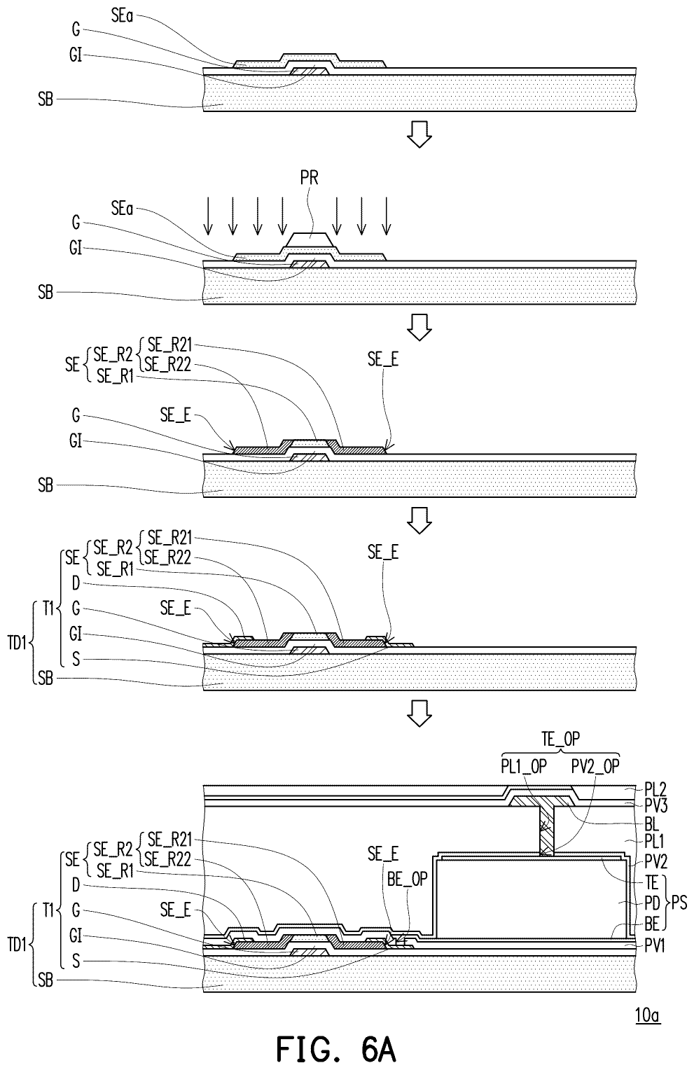

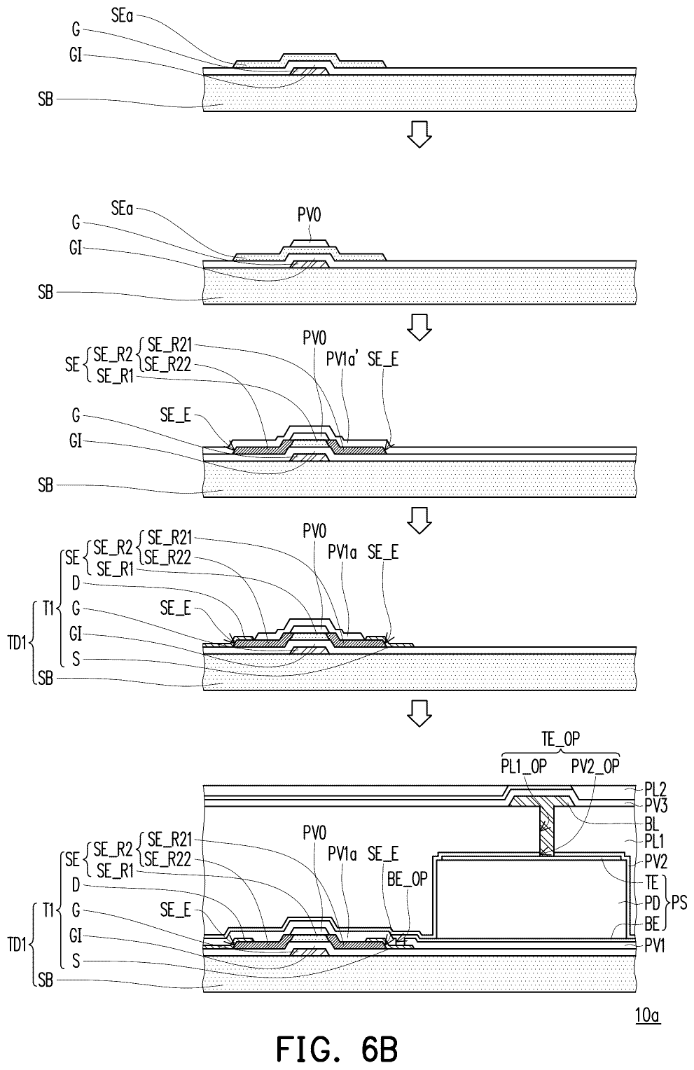

FIG. 6A is a schematic view of a flow of a method for manufacturing a photoelectric sensing device according to an embodiment of the disclosure. It is noted that, as an example, the photoelectric sensing device illustrated in FIG. 6A is the photoelectric sensing device 10a described above, but the disclosure is not limited thereto.

Referring to FIG. 6A, the method for manufacturing the photoelectric sensing device 10a of this embodiment includes the following steps.

Step (1): A gate G, a gate dielectric layer GI, and a semiconductor layer SEa are sequentially formed on a substrate SB. The gate dielectric layer GI covers the gate G, and the semiconductor layer SEa at least partially overlaps with the gate G in the normal direction n of the substrate SB. Reference may be made to the embodiments described above for the material included in the substrate SB, which will not be repeatedly described herein. A method for forming the gate G may include the following steps, for example. First, a gate material layer (not shown) is formed on the substrate SB by physical vapor deposition, metal chemical vapor deposition, or another suitable process, and then, this gate material layer is patterned to form the gate G, but the disclosure is not limited thereto. Reference may be made to the embodiments described above for the material and structure of the gate G, which will not be repeatedly described herein. A method for forming the gate dielectric layer GI may be, for example, performing chemical vapor deposition or another suitable process to form on the substrate SB, but the disclosure is not limited thereto. Reference may be made to the embodiments described above for the material and structure of the gate dielectric layer GI, which will not be repeatedly described herein.

A method for forming the semiconductor layer SEa may include the following steps, for example. First, a semiconductor material layer (not shown) is formed on the substrate SB by sputtering or another suitable process, and then, this semiconductor material layer is patterned to form the semiconductor layer SEa, but the disclosure is not limited thereto. Reference may be made to the semiconductor layer SE of the embodiments described above for the material and structure of the semiconductor layer SEa, which will not be repeatedly described herein. In this embodiment, the material of the semiconductor layer SEa includes indium gallium zinc oxide (IGZO).

Step (2): Ion implantation is performed on the semiconductor layer SEa using a photoresist PR to form a semiconductor layer SE that includes a first region SE_R1 and a second region SE_R2.

Specifically, a photoresist PR may first be disposed to cover a portion of the semiconductor layer SEa. Then, a dopant is ionized using ion implantation equipment (not shown), and the ionized dopant is implanted into the semiconductor layer SEa using an electric field and/or magnetic field. The region covered by the photoresist PR is approximately the first region SE_R1 of the semiconductor layer SE, and the region not covered by the photoresist PR is approximately the second region SE_R2 of the semiconductor layer SE. Reference may be made to the embodiments described above for the material of the dopant used in the ion implantation, which will not be repeatedly described herein. In addition, after the ion implantation is performed, the photoresist PR may be removed.

Step (3): A source S and a drain D are formed at the gate dielectric layer GI to form a transistor T1. The source S and the drain D are electrically connected to the second region SE_R2 of the semiconductor layer SE, and the source S and the drain D do not overlap with the gate G in the normal direction n of the substrate SB.

Specifically, a source and drain material layer (not shown) may be formed on the gate dielectric layer GI by physical vapor deposition, metal chemical vapor deposition, or another suitable process. Then, the source and drain material layer is patterned to form the source S and the drain D, respectively, but the disclosure is not limited thereto. Reference may be made to the embodiments described above for the materials and structures of the source S and the drain D, which will not be repeatedly described herein. In this embodiment, the source S and the drain D are, for example, respectively electrically connected to the second region SE_R21 and the second region SE_R22 located on two sides of the first region SE_R1.

In this embodiment, the transistor T1 may be formed by a back channel etch (BCE) process. That is, in the process of forming the source S and the drain D, an etch stop layer is not formed on the semiconductor layer SE, but the disclosure is not limited thereto.

It is noted that if step (2) is performed after step (3), portion that are covered by the source S and the drain D and cannot be implanted with the dopant would be present in the second region SE_R2 of the semiconductor layer SE. These portions would be respectively in contact with the source S and the drain D. When the transistor is turned on, since the current tends to flow through a current path having a low impedance, current paths flowing from the drain D to the semiconductor layer SE would be densely present at the upper half part of the portion unimplanted with the dopant. This is called the current crowding effect (CCE). The current crowding effect causes an uneven distribution of current density and makes the transistor prone to loss.

Based on the above, in this embodiment, by performing step (2) before step (3), the possibility of occurrence of the current crowding effect in the transistor T1 can be reduced.

Furthermore, in this embodiment, by forming the semiconductor layer SE before forming the source S and the drain D, the possibility of disconnection of the semiconductor layer SE can be reduced.

Step (4): A photosensitive element PS is formed on the transistor T1 to form a photoelectric sensing device 10a. The photosensitive element PS is coupled to the transistor T1, and the photosensitive element PS does not overlap with the transistor T1 in the normal direction n of the substrate SB.

A method for forming the photosensitive element PS may be, for example, sequentially forming a bottom electrode BE, a semiconductor PD, and a top electrode TE, which may be formed according to a conventional method for manufacturing a photosensitive element and will not be repeatedly described herein.

In addition, before the photosensitive element PS is formed on the transistor T1, an insulating layer PV1 may be first formed on the transistor T1. A method for forming the insulating layer PV1 may be, for example, performing chemical vapor deposition or another suitable process to form on the transistor T1, but the disclosure is not limited thereto. Reference may be made to the embodiments described above for the material and structure of the insulating layer PV1, which will not be repeatedly described herein. In this embodiment, the insulating layer PV1 has an opening BE_OP that exposes a portion of the source S, and the photosensitive element PS may be electrically connected to the transistor T1 via the opening BE_OP, but the disclosure is not limited thereto.

Furthermore, after the photosensitive element PS is formed on the transistor T1, an insulating layer PV2, a planarization layer PL1, a bias line BL, an insulating layer PV3, and a planarization layer PL2 may be sequentially formed on the photosensitive element PS. Methods for forming the insulating layer PV2, the planarization layer PL1, the insulating layer PV3, and the planarization layer PL2 may be, for example, performing chemical vapor deposition or another suitable process, and the bias line BL may be formed by physical vapor deposition, metal chemical vapor deposition, or another suitable process, but the disclosure is not limited thereto. In this embodiment, an opening PL1_OP and an opening PV2_OP respectively provided in the planarization layer PL1 and the insulating layer PV2 communicate to form an opening TE_OP and together expose a portion of the top electrode TE, and the bias line BL is disposed to be capable of being electrically connected to the photosensitive element PS via the opening TE_OP, but the disclosure is not limited thereto.

FIG. 6B is a schematic view of a flow of a method for manufacturing a photoelectric sensing device according to another embodiment of the disclosure. It is noted that the reference signs and some contents of the embodiment in FIG. 6A may apply to the embodiment in FIG. 6B, in which the same or similar reference signs represent the same or similar components, and descriptions of the same technical contents will be omitted.

Referring to FIG. 6B, the main difference between the method for manufacturing the photoelectric sensing device 10a in this embodiment and the method for manufacturing the photoelectric sensing device 10a described above lies in that, in step (2)′ of forming the semiconductor layer SE, the first region SE_R1 and the second region SE_R2 of the semiconductor layer SE are formed by chemical vapor deposition.

Specifically, after step (1) is performed, step (2)′ is performed. In step (2)′, an insulating layer PV0 may be first formed to cover a portion of the semiconductor layer SEa. Subsequently, chemical vapor deposition is performed using, for example, silane as a reaction gas to form an insulating layer PV1a′ on the semiconductor layer SEa, in which a region not covered by the insulating layer PV0 may be doped with the element (e.g., hydrogen in silane) in the reaction gas to form the second region SE_R2 of the semiconductor layer SE, and a region covered by the insulating layer PV0 is the first region SE_R1 of the semiconductor layer SE. Based on the above, the process adopted in step (2)′ to form the first region SE_R1 and the second region SE_R2 of the semiconductor layer SE may be regarded as a self-aligned process.

Subsequently, step (3) and step (4) are performed sequentially. It is noted that before step (3) is performed, the insulating layer PV1a′ is first patterned to form an insulating layer PV1a that exposes portions of the second region SE_R21 and the second region SE_R22 of the semiconductor layer SE, such that the source S and the drain D formed in step (3) can be respectively electrically connected to the second region SE_R21 and the second region SE_R22. In addition, the insulating layer PV0 and the insulating layer PV1a may subsequently form portions of the insulating layer PV1, but the disclosure is not limited thereto.

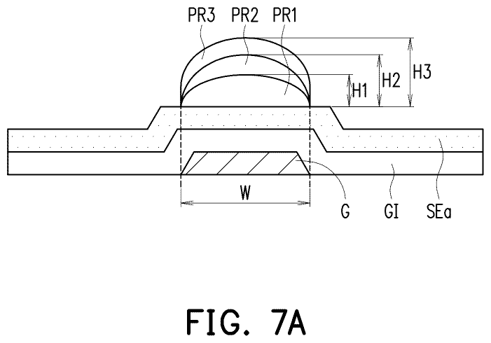

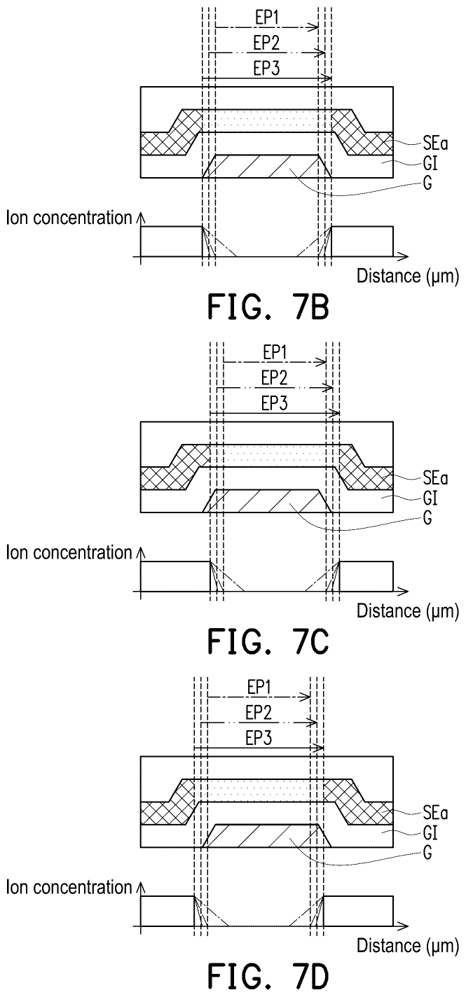

FIG. 7A is a schematic partial cross-sectional view showing application of photoresists of different heights to the method for manufacturing the photoelectric sensing device according to an embodiment, FIG. 7B is a relationship curve diagram of a concentration distribution of a dopant in the semiconductor layer according to an embodiment in FIG. 7A, FIG. 7C is a relationship curve diagram of a concentration distribution of a dopant in the semiconductor layer according to another embodiment in FIG. 7A, and FIG. 7D is a relationship curve diagram of a concentration distribution of a dopant in the semiconductor layer according to still another embodiment in FIG. 7A.

Referring to FIG. 7A, FIG. 7A shows various states when the photoresist PR in FIG. 6A is formed on the semiconductor layer SEa, including states with a first photoresist PR1, a second photoresist PR2, and a third photoresist PR3. The first photoresist PR1, the second photoresist PR2, and the third photoresist PR3 have heights different from each other.

Specifically, referring to FIG. 7B, the first photoresist PR1, the second photoresist PR2, and the third photoresist PR3 have substantially the same width W in the first direction d1 perpendicular to the normal direction n of the substrate SB. In contrast, the first photoresist PR1, the second photoresist PR2, and the third photoresist PR3 have a height H1, a height H2, and a height H3 different from each other in the normal direction n of the substrate SB, where the height H1 is less than the height H2, and the height H2 is less than the height H3. Thus, when ion implantation is performed using the first photoresist PR1, the second photoresist PR2, and the third photoresist PR3 respectively, the concentration distribution of the dopant implanted in the semiconductor layer SE will vary from each other. In the embodiment shown in FIG. 7B, it is learned that in the semiconductor layer SE formed using the third photoresist PR3 having a relatively great height H3, a relatively long current path EP3 may be formed. This is because the third photoresist PR3 can shield more dopant that is implanted from above in the ion implantation process compared to the first photoresist PR1 and the second photoresist PR2, such that the first region SE_R1 of the semiconductor layer SE formed using the third photoresist PR3 has a relatively large width in the first direction d1. In contrast, the first region SE_R1 of the semiconductor layer SE formed using the first photoresist PR1 has a relatively small width in the first direction d1, and the first region SE_R1 of the semiconductor layer SE formed using the second photoresist PR2 may have a moderate width in the first direction d1.

Referring to FIG. 7C and FIG. 7D, FIG. 7C and FIG. 7D respectively show states in which the photoresist PR is offset when formed on the semiconductor layer SEa. FIG. 7C shows that the photoresist PR is offset in the first direction d1 compared to the photoresist PR in FIG. 7B, and FIG. 7D shows that the photoresist PR is offset in a direction opposite to the first direction d1 compared to the photoresist PR in FIG. 7B. It is noted that the reference signs and some contents of the embodiment in FIG. 7B may apply to the embodiments in FIG. 7C and FIG. 7D, in which the same or similar reference signs represent the same or similar components, and descriptions of the same technical contents will be omitted.

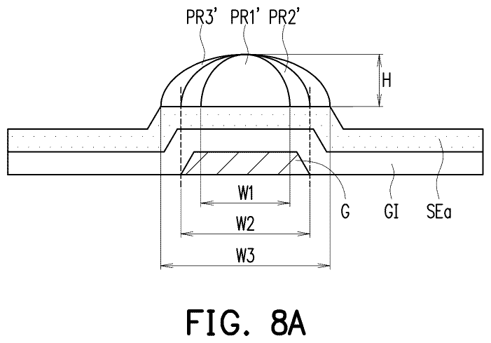

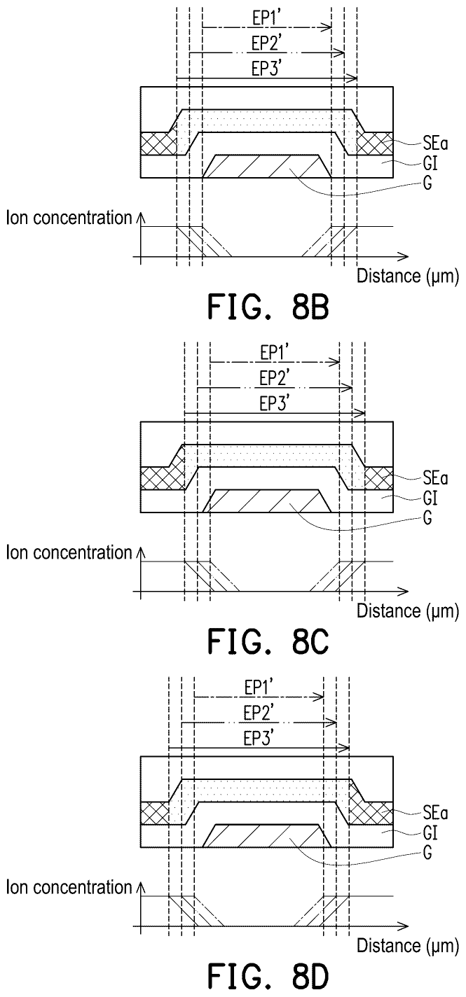

FIG. 8A is a schematic partial cross-sectional view showing application of photoresists of different widths to the method for manufacturing the photoelectric sensing device according to an embodiment. FIG. 8B is a relationship curve diagram of a concentration distribution of a dopant in the semiconductor layer according to an embodiment in FIG. 8A, FIG. 8C is a relationship curve diagram of a concentration distribution of a dopant in the semiconductor layer according to another embodiment in FIG. 8A, and FIG. 8D is a relationship curve diagram of a concentration distribution of a dopant in the semiconductor layer according to still another embodiment in FIG. 8A.

Referring to FIG. 8A, FIG. 8A shows various states when the photoresist PR in FIG. 6A is formed on the semiconductor layer SEa, including states with a first photoresist PR1′, a second photoresist PR2′, and a third photoresist PR3′. The first photoresist PR1′, the second photoresist PR2′, and the third photoresist PR3′ have widths different from each other.

Specifically, referring to FIG. 8B, the first photoresist PR1′, the second photoresist PR2′, and the third photoresist PR3′ have substantially the same height H in the normal direction n of the substrate SB. In contrast, the first photoresist PR1′, the second photoresist PR2′, and the third photoresist PR3′ respectively have a width W1, a width W2, and a width W3 different from each other in the first direction d1 perpendicular to the normal direction n of the substrate SB, where the width W1 is less than the width W2, and the width W2 is less than the width W3. Thus, when ion implantation is performed respectively using the first photoresist PR1′, the second photoresist PR2′, and the third photoresist PR3′, the concentration distribution of the dopant implanted in the semiconductor layer SE will vary from each other. In the embodiment shown in FIG. 8B, it is learned that in the semiconductor layer SE formed using the third photoresist PR3′ having a relatively large width W3, a relatively long current path EP3′ is formed. This is because the third photoresist PR3′ can shield more dopant that is implanted from above in the ion implantation process compared to the first photoresist PR1′ and the second photoresist PR2′, such that the first region SE_R1 of the semiconductor layer SE formed using the third photoresist PR3′ has a relatively large width in the first direction d1. In contrast, the first region SE_R1 of the semiconductor layer SE formed using the first photoresist PR1′ has a relatively small width in the first direction d1, and the first region SE_R1 of the semiconductor layer SE formed using the second photoresist PR2′ may have a moderate width in the first direction d1.

Referring to FIG. 8C and FIG. 8D, FIG. 8C and FIG. 8D respectively show states in which the photoresist PR is offset when formed on the semiconductor layer SEa. FIG. 8C shows that the photoresist PR is offset in the first direction d1 compared to the photoresist PR in FIG. 8B, and FIG. 8D shows that the photoresist PR is offset in a direction opposite to the first direction d1 compared to the photoresist PR in FIG. 8B. It is noted that the reference signs and some contents of the embodiment in FIG. 8B may apply to the embodiments in FIG. 8C and FIG. 8D, in which the same or similar reference signs represent the same or similar components, and descriptions of the same technical contents will be omitted.

### EXPERIMENTAL EXAMPLES

Experimental examples will be described below to illustrate the disclosure, but these experimental examples are intended to be illustrative and are not intended to limit the scope of the disclosure.

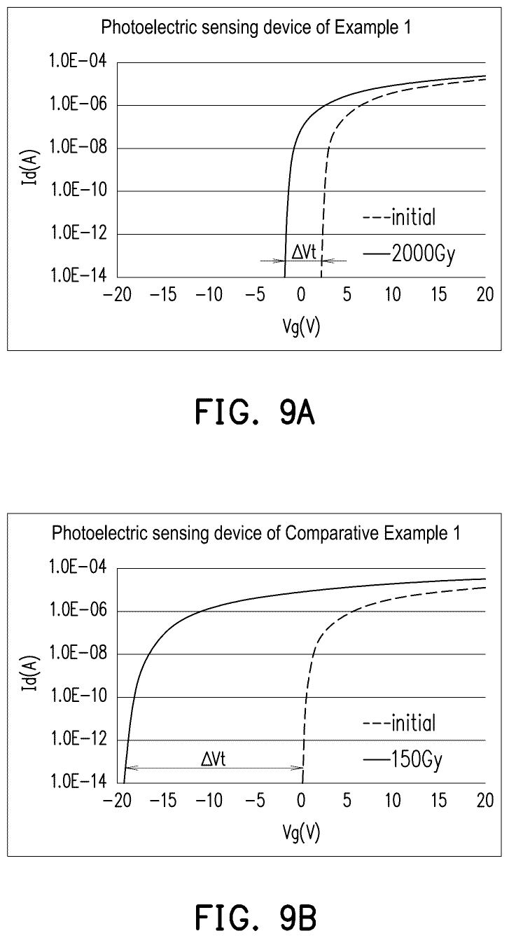

FIG. 9A is a drain current-gate voltage (Id-Vg) characteristic curve diagram of the transistor in the photoelectric sensing device according to Example 1 of the disclosure, and FIG. 9B is a drain current-gate voltage characteristic curve diagram of the transistor in the photoelectric sensing device according to Comparative example 1.

The photoelectric sensing device used in Example 1 was the photoelectric sensing device 10a shown in FIG. 1A and FIG. 1B, in which the gate dielectric layer GI included one layer of silicon nitride, and the gate dielectric layer GI was in contact with the semiconductor layer SE. Reference may be made to the embodiments described above for the other components in the photoelectric sensing device 10a, which will not be repeatedly described herein.

The photoelectric sensing device used in Comparative example 1 was substantially the same as the photoelectric sensing device 10a used in Example 1, and the difference was that the photoelectric sensing device of Comparative example 1 further included a silicon oxide layer, and the silicon oxide layer was disposed between the gate dielectric layer GI and the semiconductor layer SE and was in contact with the semiconductor layer SE. In addition, both the photoelectric sensing device 10a of Example 1 and the photoelectric sensing device of Comparative example 1 were used to detect an X-ray source of 80 kV.

### Example 1

In Example 1, the transistor T1 absorbed radiation energy of 2000 gray (Gy), and the threshold voltage shift of the transistor T1 in the radiation hardness of the photoelectric sensing device 10a was approximately 4 V to 6 V.

### Comparative Example 1

In Comparative example 1, the transistor absorbed radiation energy of 150 gray, and the threshold voltage shift of the transistor in the radiation hardness of the photoelectric sensing device was approximately 15 V to 20 V.

Based on the above, since the portion of the gate dielectric layer GI of the transistor T1 in the photoelectric sensing device 10a of Example 1 that was in contact with the semiconductor layer SE was a silicon nitride layer having a relatively small energy gap, it could have better radiation hardness compared to the transistor in the photoelectric sensing device of Comparative example 1.

In summary of the above, in the transistor device (photoelectric sensing device) provided according to an embodiment of the disclosure, the drain does not overlap with the gate in the normal direction of the substrate, which can reduce the parasitic capacitance generated between the drain and the gate such that the transistor can have a relatively small gate-drain capacitance and have relatively good electrical performance. Furthermore, it is also possible to reduce the load of the data line electrically connected to the drain.

In the transistor device (photoelectric sensing device) provided according to another embodiment of the disclosure, the portion of the gate dielectric layer that is in contact with the semiconductor layer includes a silicon nitride-based material and has a smaller energy gap compared to a silicon oxide layer. Thus, the transistor in the transistor device (photoelectric sensing device) can have a relatively good radiation hardness.

What is claimed is:

1. A transistor device comprising:
a substrate; and
a transistor disposed on the substrate and comprising:
a gate;
a gate dielectric layer disposed on the gate;
a semiconductor layer disposed on the gate dielectric layer and comprising a first region and a second region, wherein the first region at least partially overlaps with the gate in a normal direction of the substrate, the second region extends from the first region to an edge of the semiconductor layer, and the second region further comprises a dopant compared to the first region; and
a source and a drain that are disposed on the semiconductor layer and are electrically connected to the second region of the semiconductor layer, wherein at least one of the source and the drain does not overlap with the gate in the normal direction of the substrate.

2. The transistor device according to claim 1, wherein the source and the drain do not overlap with the gate in the normal direction of the substrate.

3. The transistor device according to claim 1, wherein a material of the semiconductor layer comprises a metal oxide.

4. The transistor device according to claim 1, wherein the dopant comprises B, Ar, P, F, or a combination thereof.

5. The transistor device according to claim 1, wherein an impedance of the second region is less than an impedance of the first region.

6. The transistor device according to claim 1, further comprising:
a scan line disposed on the substrate and coupled to the gate of the transistor; and
a data line disposed on the substrate and coupled to the drain of the transistor.

7. The transistor device according to claim 6, wherein the source of the transistor at least partially overlaps with the gate in the normal direction of the substrate.

8. The transistor device according to claim 7, wherein a distance between the drain and the gate in a specific direction is greater than 0.5 micrometers, a width in the specific direction of a portion of the source that overlaps with the gate is less than 4 micrometers, and the specific direction is perpendicular to the normal direction of the substrate.

9. The transistor device according to claim 6, wherein the data line and the drain of the transistor belong to layers different from each other, and the data line is farther from the gate of the transistor in the normal direction of the substrate than from the drain.

10. The transistor device according to claim 1, wherein a width of the drain in a specific direction and a width of the source in the specific direction are less than a width of the semiconductor layer in the specific direction.

11. The transistor device according to claim 1, wherein a width of the drain in a specific direction and a width of the source in the specific direction are greater than a width of the semiconductor layer in the specific direction.

12. A photoelectric sensing device comprising:
a substrate;
a transistor disposed on the substrate and comprising:
a gate;
a gate dielectric layer disposed on the gate;
a semiconductor layer disposed on the gate dielectric layer, wherein a portion of the gate dielectric layer that is in contact with the semiconductor layer comprises a silicon nitride-based material; and
a source and a drain that are disposed on the semiconductor layer; and
a photosensitive element disposed on the substrate and coupled to the transistor, wherein
a threshold voltage shift of the transistor in a radiation hardness of the photoelectric sensing device is 0 V to 8 V.

13. The photoelectric sensing device according to claim 12, wherein the silicon nitride-based material comprises SiN, SiON, SiCN, SiOCN, or a combination thereof.

14. The photoelectric sensing device according to claim 12, wherein the gate dielectric layer comprises a multi-layer structure.

15. The photoelectric sensing device according to claim 12, wherein the semiconductor layer comprises a first region and a second region, the first region at least partially overlaps with the gate in a normal direction of the substrate, the second region extends from the first region to an edge of the semiconductor layer, and the second region further comprises a dopant compared to the first region.

16. The photoelectric sensing device according to claim 15, wherein the source and the drain are electrically connected to the second region of the semiconductor layer, and at least one of the source and the drain does not overlap with the gate in the normal direction of the substrate.

17. The photoelectric sensing device according to claim 12, further comprising:
a scan line disposed on the substrate and coupled to the gate of the transistor;
a data line disposed on the substrate and coupled to the drain of the transistor; and
a bias line disposed on the substrate and coupled to the photosensitive element.

18. The photoelectric sensing device according to claim 17, wherein the data line and the bias line belong to a same layer.

19. The photoelectric sensing device according to claim 12, wherein the photosensitive element at least partially overlaps with the transistor in a normal direction of the substrate.

20. The photoelectric sensing device according to claim 12, wherein the photosensitive element does not overlap with the transistor in a normal direction of the substrate.
